(19) United States
(12) Patent Application Publication
(10) Pub. No.: US 2011/0042125 A1
(43) Pub. Date: Feb. 24, 2011

(54) CONDUCTIVE INK, METHOD OF PREPARING METAL WIRING USING CONDUCTIVE INK, AND PRINTED CIRCUIT BOARD PREPARED USING METHOD

(75) Inventors: Jong-Hee LEE, Suwon-si (KR); Jae-Myung Kim, Suwon-si (KR); Kyu-Nam Joo, Suwon-si (KR); So-Ra Lee, Suwon-si (KR); Jae-Sun Jeong, Suwon-si (KR)

Correspondence Address: KNOBBE MARTENS OLSON & BEAR LLP, 2040 MAIN STREET, FOURTEENTH FLOOR, IRVINE, CA, 92614, US

(73) Assignee: Samsung SDI Co., Ltd., Suwon-si (KR)

(21) Appl. No.: 12/816,564

(22) Filed: Jun. 16, 2010

(30) Foreign Application Priority Data
Aug. 19, 2009 (KR) 10-2009-0076731

(51) Int. Cl. H05K 1/00; H01B 1/22; B05D 5/12

(52) U.S. Cl. 174/250; 252/512; 252/514; 252/513; 427/98.4; 977/773; 977/932

(57) ABSTRACT

A conductive ink including metal ions, a functional solvent, and a capping agent, a method of preparing a metal wiring using the conductive ink, and a printed circuit board including the metal wiring.

### CROSS-REFERENCE TO RELATED APPLICATION

This application claims the benefit of Korean Patent Application No. 10-2009-0076731, filed on Aug. 19, 2009, in the Korean Intellectual Property Office, the disclosure of which is incorporated herein, by reference.

### BACKGROUND

1. Field

One or more embodiments of the present disclosure relate to a conductive ink, a method of preparing metal wirings using the conductive ink, and a printed circuit board prepared using the method.

2. Description of the Related Art

Recently, the development of small-sized and high-performance electronic devices has created a need for miniaturized wiring. Active research has been conducted on developing inkjet methods for preparing fine wiring, using conductive inks that include metal nanoparticles. When such an inkjet method is used, fine wiring is manufactured at a low cost, by printing the ink on a printed board, and then sintering the ink.

The metal nanoparticles included in a conductive ink generally have average diameters of several nanometers and are prepared using vapor phase, physical, or chemical methods, as disclosed in Korean Patent Publication No. 2005-0101101. In order to form a conductive ink including the metal nanoparticles, the metal nanoparticles are dispersed with a capping agent and additives, in a polar or nonpolar solvent, according to the properties of wirings to be formed using the ink.

Conventionally, in order to smoothly eject ink, metal nanoparticles having a size from several to several tens of nanometers are included in a conductive ink. However, the aggregation and/or growth of the metal particles should be prevented in an ink, prior to application. If a long period of time elapses, increases in the diameters and aggregation inevitably occur in a conductive ink including metal nanoparticles, thereby reducing the lifetime of the conductive ink. In addition, when the ink is printed on a printed board, a nozzle of a printing head may be clogged. In order to normally eject ink, nanoparticles are separated using a filtering process. However, it is difficult to adjust an amount of metal nanoparticles included in an ink solution after the filtering process, and material losses may occur.

### SUMMARY

One or more embodiments of the present disclosure include a conductive ink to form a metal wiring, wherein the conductive ink may be stored for a long period of time, by preventing aggregation between metal nanoparticles.

One or more embodiments of the present disclosure include a method of preparing a metal wiring using the conductive ink, whereby nozzle clogging is prevented and loss in materials is reduced.

One or more embodiments of the present disclosure include a printed circuit board including a metal wiring, produced using the method.

According to one or more embodiments of the present disclosure, a conductive ink includes metal ions, a functional solvent, and a capping agent.

According to one or more embodiments of the present disclosure, provided is a conductive ink including from about 20 to about 50 parts by weight of metal ions and from about 70 to about 110 weight by weight of a capping agent, based on 100 parts by weight of a functional solvent.

According to one or more embodiments of the present disclosure, the metal ions may be ions of at least one selected from the group consisting of silver (Ag), gold (Au), platinum (Pt), copper (Cu), nickel (Ni), and palladium (Pd).

According to one or more embodiments of the present disclosure, the functional solvent may be at least one selected from the group consisting of N-dimethylformamide, ethylene glycol, diethylene glycol, glycerol, and polyethylene glycol.

According to one or more embodiments of the present disclosure, the capping agent may be at least one selected from the group consisting of dextrin, polyvinylpyrrolidone, polyacrylate and polyvinyl alcohol.

According to one or more embodiments of the present disclosure, a method of preparing a metal wiring includes: printing the conductive ink on a substrate; heating the printed substrate to form metal nanoparticles; and heat-treating the metal nanoparticles, to form the wiring.

According to one or more embodiments of the present disclosure, the printed substrate may be heated at a temperature of about 50 to about 85° C.

According to one or more embodiments of the present disclosure, the metal nanoparticles may have a mean diameter (D50) of about 20 to about 50 nm.

According to one or more embodiments of the present disclosure, the heat-treating may be performed for about 10 minutes to about 1 hour, at a temperature of about 150 to about 200° C.

According to one or more embodiments of the present disclosure, a printed circuit board includes a metal wiring manufactured using the above-described method.

According to one or more embodiments of the present disclosure, the metal wiring may include a conductive pattern having a line width of about 0 to about 40 μm.

Additional aspects and/or advantages of the disclosure will be set forth in part in the description which follows and, in part, will be obvious from the description, or may be learned by practice of the disclosure.

### BRIEF DESCRIPTION OF THE DRAWINGS

These and/or other aspects and advantages of the present disclosure will become apparent and more readily appreciated from the following description of the exemplary embodiments, taken in conjunction with the accompanying drawings, of which:

FIG. 1 is a schematic diagram for explaining a method of preparing metal wiring by using a conductive ink, according to an exemplary embodiment of the present disclosure; and

FIG. 2 shows an analysis result of grain sizes of metal nanoparticles, according to an exemplary embodiment of the present disclosure.

### DETAILED DESCRIPTION

Reference will now be made in detail to the exemplary embodiments of the present disclosure, examples of which are illustrated in the accompanying drawings, wherein like reference numerals refer to the like elements throughout. The exemplary embodiments are described below, in order to explain the aspects of the present disclosure, by referring to the figures.

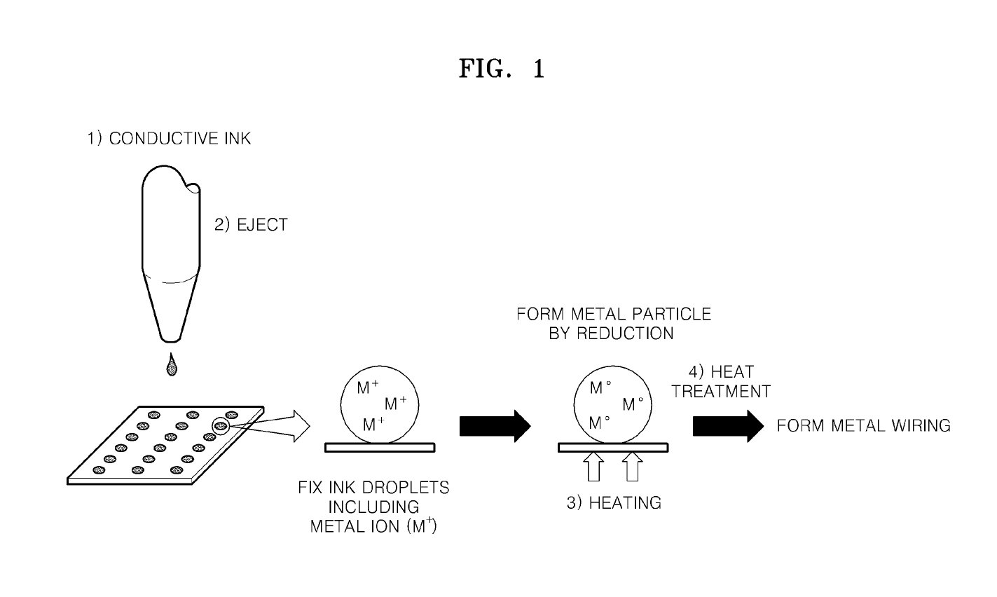

FIG. 1 is a schematic diagram illustrating a method of preparing a metal wiring using a conductive ink, according to an exemplary embodiment of the present disclosure. Referring to FIG. 1, the method includes: printing a conductive ink including metal ions, a functional solvent, and a capping agent on a substrate; heating the printed substrate to form metal particles (nanoparticles) by reducing the metal ions; and heat-treating the metal particles, to form the metal wiring.

Prior to the heating of the printed substrate, the conductive ink includes the metal ions instead of metal particles. The metal ions are reduced during the heating of the printed substrate, to form the metal particles. Thus, since the metal particles are formed after being printed on the substrate, metal particle growth and/or aggregation in the ink may be prevented, prior to printing.

According to an exemplary embodiment of the present disclosure, provided is a conductive ink that includes a functional solvent and metal ions. The functional solvent operates both as a solvent and a reducing agent, with respect to the metal ions. The functional solvent may have no reducing power with respect to the metal ions, at room temperature. However, when the conductive ink reaches a predetermined temperature, the functional solvent may acquire reducing power. For example, the functional solvent may be at least one selected from the group consisting of N-dimethylformamide, ethylene glycol, diethylene glycol, glycerol, and polyethylene glycol. The functional solvent allows for the long-term storage of the conductive ink, without the formation and/or aggregation of metal particles therein.

According to an exemplary embodiment of the present disclosure, the conductive ink includes metal ions instead of metal particles. The metal ions may be reduced by the functional solvent at a predetermined temperature, to form metal particles.

The metal ions may be formed by adding a metal nitride represented by M(NO)n or a metal halide precursor represented by MXm, to the functional solvent. In this case, element M may be any common conductive metal. For example, element M may be at least one selected from the group consisting of silver (Ag), gold (Au), platinum (Pt), copper (Cu), nickel (Ni), and palladium (Pd).

About 20 to about 50 parts by weight of the metal ions, based on 100 parts by weight of the functional solvent, may be included in the conductive ink. When an amount of the metal ions is within this range, the ink may exhibit a desired dispersion stability, reduction reaction efficiency, and inkjet printing suitability. As a result, the ink is well suited for the production of metal wiring.

According to an embodiment of the present disclosure, the conductive ink includes a capping agent that delays grain growth of a metal and prevents aggregation between particles. Generally, a compound containing oxygen (O), nitrogen (N), or sulfur (S) may be used as the capping agent. In particular, in order to prevent an increase in the resistance of metal wirings, due to xanthan production after performing a sintering operation, the capping agent may be at least one selected from the group consisting of dextrin, polyvinylpyrrolidone, polyacrylate, and polyvinyl alcohol.

In the conductive ink, the capping agent may be completely decomposed at a much lower temperature, as compared to a temperature at which the capping agent alone would decompose, due to the high thermal conduction of the metal particles capped by the capping agent, which are formed from the metal ions. Thus, the capping agent may be easily removed from the printed substrate, during the heat treatment.

An amount of the capping agent may vary according to an amount of the metal ions. According to an exemplary embodiment of the present disclosure, about 70 to about 110 parts by weight of the capping agent, based on 100 parts by weight of the functional solvent, may be included in the conductive ink. When the amount of the capping agent is within this range, the premature formation of metal particles may be prevented, and an amount of xanthan may be reduced.

According to an exemplary embodiment of the present disclosure, the conductive ink may also include additives, such as an organic solvent, a binder, a dispersion agent, a thickening agent, and a surfactant. These components are well known in the art and thus, will not be described in detail.

According to an exemplary embodiment of the present disclosure, since the conductive ink does includes metal ions, metal particle growth and aggregation is essentially prevented. Thus, even if a long period of time elapses, an original state of the conductive ink may be maintained.

The conductive ink may be printed on the substrate using any well known printing method. In particular, the conductive ink may be printed using inkjet printing, screen printing, and so on. Inkjet printing includes any well known method of ejecting ink to print a pattern. In inkjet printing, a wiring diagram is completed according to a digital printing method. When the wiring diagram is printed, metal wiring patterns are formed by ejecting the conductive ink on a substrate such as a resin film, in a desired form of wirings, according to the printed wiring diagram.

The substrate, on which the conductive ink is printed, may be any well known substrate, such as, a glass film, a circuit board, or a resin film. The resin film may be a common resin film used in a printed circuit board (PCB) or a flexible printed circuit board (FPCB). In addition, the resin film may be a heat-resistant resin film including polytetrafluoroethylene (PTFE) or polyimide.

In a method of preparing metal wirings, according to an exemplary embodiment of the present disclosure, since the conductive ink including the metal ions is used, a nozzle of a print head may be prevented from clogging. Thus, the redispersion of metal nanoparticles and/or the filtering of aggregated particles are not needed. As a result, material losses may be reduced, and the method is simplified.

In a method of preparing metal wirings, according to an exemplary embodiment of the present disclosure, the conductive ink is printed onto the substrate, and then the printed substrate is heated to a predetermined temperature. The functional solvent has no reducing power with respect to the metal ions, at room temperature. However, when heating is performed, the functional solvent reduces the metal ions, to form metal particles.

The heating temperature may vary, according to the type of functional solvent in the ink. For example, heating may be performed for from about 30 seconds to about 3 minutes, at a temperature of about 50 to about 85° C.

The atmosphere in which the heating occurs is not particularly limited. For example, the heating may be performed under an inert atmosphere such as nitrogen (N), helium (He), or argon (Ar). The heating may also be performed in an ambient atmosphere, for convenience of operations.

Since the metal ions are deposited directly on the substrate, without having being grown or aggregated, the average diameters of the metal particles formed from the metal ions may be very narrowly adjusted to 50 nm, or less. Thus, fine metal wirings may be obtained using the present method.

In a method of preparing a metal wiring, according to an exemplary embodiment of the present disclosure, a heat treatment operation is performed after a first heating operation is performed. During the heat treatment, organic materials, such as the capping agent, are removed, and the metal nanoparticles may be combined to forming the wiring.

The printed substrate should not be degraded due to the heat treatment. The heat treatment may be performed for a short time period, at a high temperature, in order to prevent the metal particles from dispersing. In detail, the heat treatment may be performed for from about 10 minutes to about 1 hour. For example the heat treatment may be performed for from about 20 minutes to about 1 hour, at a temperature of about 150 to about 350° C. The heat-treatment may be conducted in an inert or ambient atmosphere, as described above.

The printed substrate manufactured using the above-described method may be a general printed circuit board or a flexible printed circuit board. In particular, since the printed substrate according to the present disclosure may have thin wirings, miniaturization and high-integration may be obtained, to form a desired flexible printed circuit board.

In addition, the printed circuit board may be applicable for use in various electric devices, such as portable devices, industrial devices, office devices, and home devices. A printed circuit board including wiring having a line width of 40 μm or less may be formed using the above-described method.

Hereinafter, one or more embodiments of the present disclosure will be described in detail, with reference to the following examples. However, these examples are not intended to limit the purpose and scope of the exemplary embodiments of the present disclosure.

### Example 1

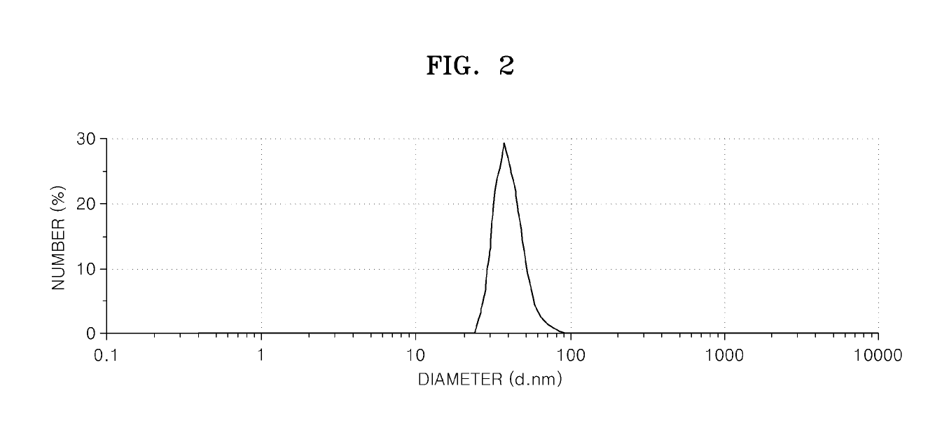

92.3 parts by weight of polyvinyl alcohol (molecular weight 10,000) and 61.5 parts by weight of AgNO₃ were added to 100 parts by weight of polyethylene glycol #100. The resultant was stirred at room temperature, until the AgNO₃ was completely dissolved, to prepare a conductive ink including metal ions. The conductive ink was printed on a glass substrate using an inkjet printer. The printed glass substrate was heated at a temperature of 75° C., to generate Ag nanoparticles. FIG. 2 shows an analysis of the grain sizes of the Ag nanoparticles. The Ag nanoparticles were heat-treated in a sintering furnace for three minutes, at a temperature of 150° C., to prepare micro-wiring.

### Example 2

A conductive ink was prepared in the same manner as in Example 1, except that polyethylene glyco #400 was substituted for the polyethylene glycol #100. The conductive ink was printed on a glass substrate using an inkjet printer. The printed glass substrate was heated at a temperature of 65° C., to generate Ag nanoparticles. Then, the glass substrate was heat-treated in a sintering furnace for 30 minutes, at a temperature of 150° C., to prepare micro-wiring.

As described above, according to the one or more of embodiments of the present disclosure, since a conductive ink includes metal ions, an unwanted increase in diameter and/or particle aggregation may be essentially prevented. Thus, the conductive ink may have a long storage life. By using the conductive ink, the nozzle of a print head may be prevented from clogging. Thus, the redispersion of metal nanoparticles and/or a filtering process for separating aggregated particles are not needed. Accordingly, material losses may be prevented, and metal wiring may be produced by a simplified method. According to the method, the distribution of particle diameters of the metal particles may be finely adjusted.

Although a few exemplary embodiments of the present disclosure have been shown and described, it would be appreciated by those skilled in the art that changes may be made in these exemplary embodiments, without departing from the principles and spirit of the present disclosure, the scope of which is defined in the claims and their equivalents.

What is claimed is:

1. A conductive ink to form a metal wiring, comprising:
metal ions;
a functional solvent; and
a capping agent.

2. The conductive ink of claim 1, wherein the conductive ink comprises about 20 to about 50 parts by weight of the metal ions, and about 70 to about 110 parts by weight of the capping agent, based on 100 parts by weight of the functional solvent.

3. The conductive ink of claim 1, wherein the metal ions are ions of a metal selected from the group consisting of silver (Ag), gold (Au), platinum (Pt), copper (Cu), nickel (Ni), palladium (Pd), and a combination thereof.

4. The conductive ink of claim 1, wherein the functional solvent is selected from the group consisting of N-dimethylformamide, ethylene glycol, diethylene glycol, glycerol and polyethylene glycol, and a combination thereof.

5. The conductive ink of claim 1, wherein the capping agent is selected from the group consisting of dextrin, polyvinylpyrrolidone, polyacrylate, polyvinyl alcohol, and a combination thereof.

6. A method of preparing a metal wiring, the method comprising:
printing the conductive ink of claim 1 on a substrate;
heating the printed substrate to form metal nanoparticles using the metal ions; and
heat-treating the metal nanoparticles, to form the metal wiring.

7. The method of claim 6, wherein the heating comprises heating the printed substrate at a temperature of from about 50° C. to about 85° C.

8. The method of claim 6, wherein the metal nanoparticles have a mean diameter (D50) of from about 20 nm to about 50 nm.

9. The method of claim 6, wherein the heat-treating is performed for about 10 minutes to about 1 hour, at a temperature of from about 150° C. to about 200° C.

10. A printed circuit board comprising a metal wiring manufactured using the method of claim 6.

11. The printed circuit board of claim 10, wherein the metal wiring comprises a line width of about 0 to about 40 μm.

12. A conductive ink to form a metal wiring, comprising:
metal ions;
a functional solvent to prevent the reduction of the ions at a first temperature, and to reduce the ions to form metal nanoparticles, at a higher second temperature; and
a capping agent.

13. The conductive ink of claim 12, wherein the capping agent is selected from the group consisting of dextrin, polyvinylpyrrolidone, polyacrylate, polyvinyl alcohol, and a combination thereof.

14. The conductive ink of claim 12, wherein the functional solvent is selected from the group consisting of N-dimethylformamide, ethylene glycol, diethylene glycol, glycerol and polyethylene glycol, and a combination thereof.

15. The conductive ink of claim 12, wherein the second temperature is from about 50° C. to about 85° C.

16. A method of preparing a metal wiring, the method comprising:
printing the conductive ink of claim 12 on a substrate;
heating the printed substrate to form metal nanoparticles using the metal ions; and
heat-treating the metal nanoparticles, to form the metal wiring.
